(19) United States
(12) Patent Application Publication
(10) Pub. No.: US 2025/0038009 A1
(43) Pub. Date: Jan. 30, 2025

(54) STRESS RELIEF SAWN QUAD FLAT NO-LEAD SEMICONDUCTOR PACKAGE

(71) Applicant: Texas Instruments Incorporated, Dallas, TX (US)

(72) Inventors: Kengo Aoya, Beppu-shi (JP); Masamitsu Matsuura, Beppu-shi (JP); Daiki Komatsu, Beppu-shi (JP)

(21) Appl. No.: 18/361,747

(22) Filed: Jul. 28, 2023

(51) Int. Cl. H01L 21/48; H01L 21/56; H01L 23/31; H01L 23/495

(52) U.S. Cl. CPC H01L 21/4842; H01L 21/565; H01L 23/3107; H01L 23/49548

(57) ABSTRACT

A semiconductor package has a relief recess in the mold compound, extending around the perimeter over the leads. The relief recess has a relief width greater than a thickness of the leads under the relief recess. Top surfaces of the leads may be exposed at the relief recess, or may be covered by the mold compound under the relief recess. In both cases, a height difference between the mold compound under the relief recess and the leads under the relief recess is less than the thickness of the leads under the relief recess. A majority of exposed side faces of the leads are characteristic of sawn surfaces, which includes leads being free of vertical striations or having burrs along bottom edges. The semiconductor package is singulated by sawing through the leads.

### TECHNICAL FIELD

This disclosure relates to the field of semiconductor packages. More particularly, but not exclusively, this disclosure relates to quad flat no-lead semiconductor packages.

### BACKGROUND

Quad flat no-lead (QFN) packages have emerged as a popular choice for compact and high-performance integrated circuit packaging. QFN packages have metal pads on the bottom surface of the package, enabling a higher pin density in a smaller form factor. QFN packages exhibit shorter electrical paths, leading to lower inductance, reduced parasitic capacitance, and enhanced high-frequency performance. QFN packages offer simplified assembly processes, increased automation compatibility, and reduced material costs.

### SUMMARY

A semiconductor package has leads around a perimeter of the semiconductor package and a microelectronic component electrically coupled to a plurality of the leads. A mold compound, which is electrically insulating, contacts the leads and the microelectronic component. The mold compound is recessed around the perimeter to provide a relief recess over a portion of each of the leads. The relief recess has a relief width greater than a thickness of the leads under the relief recess. In one aspect, top surfaces of the leads may be exposed at the relief recess. In another access, the top surfaces of the leads may be covered by the mold compound under the relief recess. In both aspects, a height difference between the mold compound under the relief recess and the leads under the relief recess is less than the thickness of the leads under the relief recess. Exposed side faces of a majority of the leads are characteristic of sawn surfaces. In one aspect, being characteristic of sawn surfaces may include the exposed side faces of the majority of the leads being free of vertical striations. In another aspect, being characteristic of sawn surfaces may include the exposed side faces of the majority of the leads having burrs along bottom edges.

The semiconductor package is formed by electrically coupling the microelectronic component to the leads, and forming the mold compound on the leads and on the microelectronic component. A relief recess is formed in the mold compound around the perimeter over the leads, so that the mold compound is laterally recessed around the perimeter to provide the relief recess. The semiconductor package is singulated by sawing through the leads. In one aspect, the mold compound may be laterally recessed before singulating the semiconductor package. In another aspect, the mold compound may be laterally recessed after singulating the semiconductor package.

### BRIEF DESCRIPTION OF THE FIGURES

FIG. 1A through FIG. 1H are top views, cross sections, and perspectives of a semiconductor package having a relief recess, depicted in successive stages of an example method of formation.

FIG. 2A through FIG. 2H are top views, cross sections, and perspectives of another semiconductor package having a relief recess, depicted in successive stages of an example method of formation.

FIG. 3A through FIG. 3D are cross sections and perspectives of a further semiconductor package having a relief recess, depicted in successive stages of an example method of formation.

FIG. 4A and FIG. 4B are cross sections of another semiconductor package having a relief recess, depicted in successive stages of an example method of formation.

FIG. 5A through FIG. 5C are cross sections of a further semiconductor package having a relief recess, depicted in successive stages of an example method of formation.

FIG. 6A through FIG. 6C are cross sections of a further semiconductor package having a relief recess, depicted in successive stages of an example method of formation.

FIG. 7 is a cross section of a semiconductor package singulated by a punched process.

FIG. 8 is a cross section of a semiconductor package having exposed side faces of leads that are characteristic of sawn surfaces.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

A semiconductor package has leads around a perimeter of the semiconductor package. The leads are attached to a lead frame. A microelectronic component is electrically coupled to a plurality of the leads. A mold compound, which is electrically insulating, is formed on the leads and the microelectronic component. The mold compound is recessed around the perimeter to provide a relief recess over a portion of each of the leads. The relief recess has a relief width, in a direction perpendicular to the perimeter, greater than a thickness of the leads under the relief recess. In one version, the relief recess may be formed so that top surfaces of the leads may be exposed at the relief recess. In another version, the relief recess may be formed so that the top surfaces of the leads may be covered by the mold compound under the relief recess. A height difference between the mold compound under the relief recess and the leads under the relief recess is less than the thickness of the leads under the relief recess.

The semiconductor package is singulated by sawing through the leads. Singulation by sawing enables forming a plurality of semiconductor packages concurrently using the lead frame, because the mold compound can be formed on all the semiconductor packages in one operation, which is not cost effective for punched (stamped) singulation. Exposed side faces of a majority of the leads are characteristic of sawn surfaces. In one aspect, being characteristic of sawn surfaces may include the exposed side faces of the majority of the leads being free of vertical striations. In another aspect, being characteristic of sawn surfaces may include the exposed side faces of the majority of the leads having burrs along bottom edges. In one version, the mold compound may be laterally recessed before singulating the semiconductor package. In another version, the mold compound may be laterally recessed after singulating the semiconductor package.

In an electronic system that includes the semiconductor package, the leads are attached to a substrate, such as a printed circuit board, with solder joints connecting the leads to terminals of the substrate. Stress is generated in the solder joints due to thermal expansion mismatch between the semiconductor package and the substrate. The relief recess may advantageously reduce the stress by reducing transmission of stress in the mold compound to the leads.

It is noted that terms such as top, bottom, over, under, and below may be used in this disclosure. These terms should not be construed as limiting the position or orientation of a structure or element, but should be used to provide spatial relationship between structures or elements.

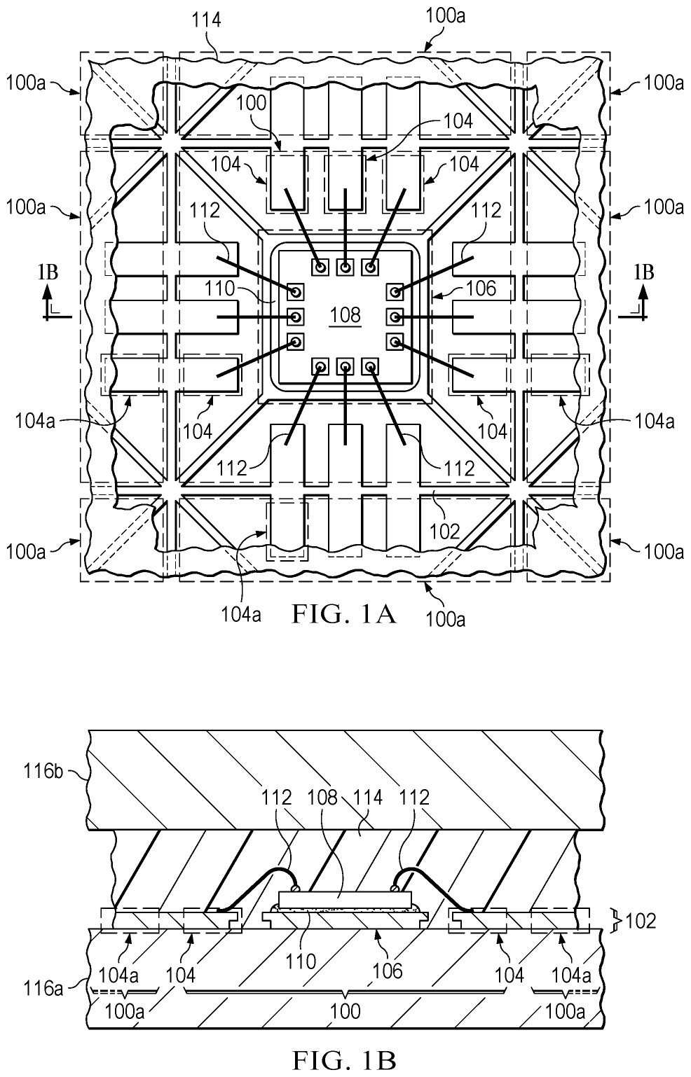

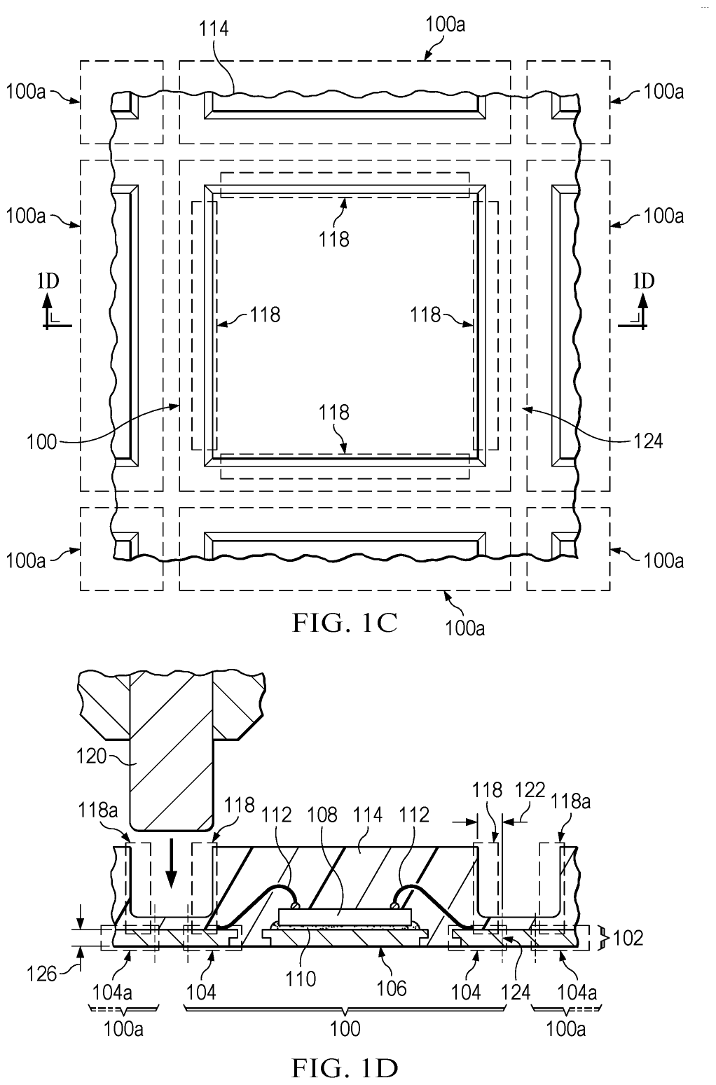

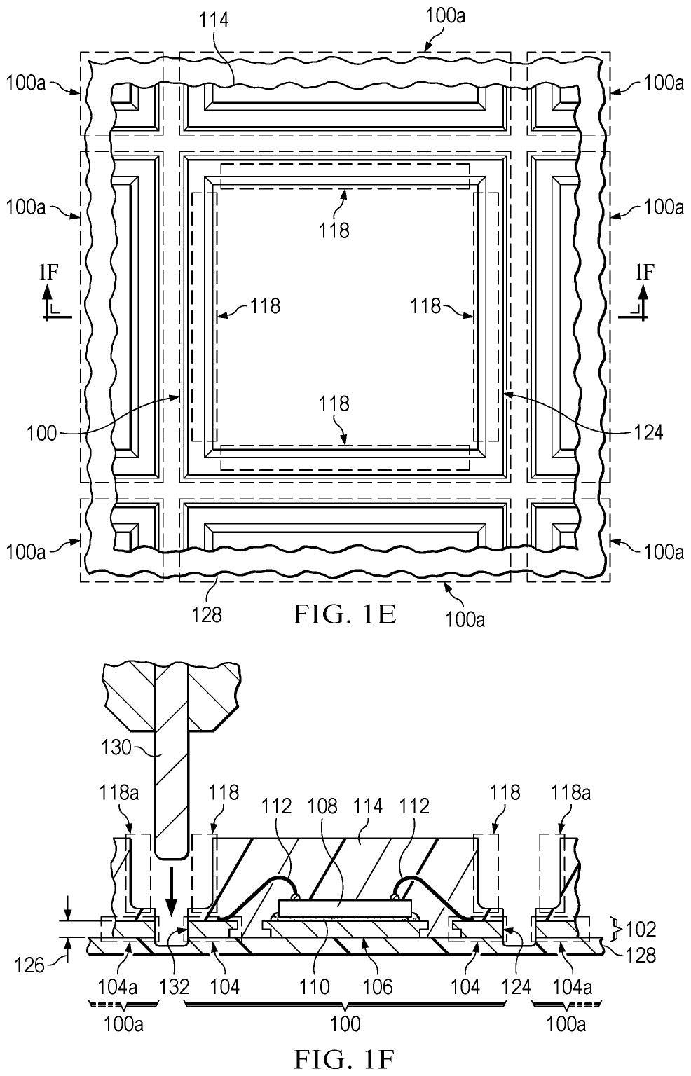

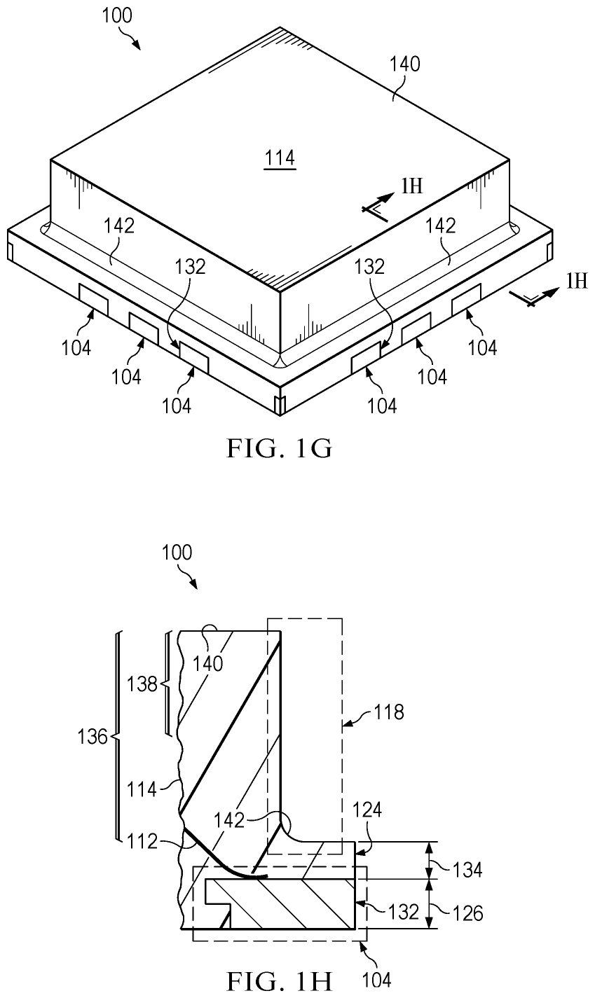

FIG. 1A through FIG. 1H are top views, cross sections, and perspectives of a semiconductor package having a relief recess, depicted in successive stages of an example method of formation. FIG. 1A is a top view of the semiconductor package and FIG. 1B is a cross section of the semiconductor package of FIG. 1A at a first stage of formation. Referring to FIG. 1A and FIG. 1B, the semiconductor package 100 is formed using a lead frame 102. The lead frame 102 of this example accommodates additional semiconductor packages 100a adjacent to the semiconductor package 100.

The semiconductor package 100 includes a plurality of leads 104 of the lead frame 102. Similarly, the additional semiconductor packages 100a also include pluralities of additional leads 104a of the lead frame 102. The semiconductor package 100 of this example includes a die pad 106 of the lead frame 102. Similarly, the additional semiconductor packages 100a also include additional die pads, not specifically shown.

A microelectronic component 108 is attached to the die pad 106. The microelectronic component 108 may be manifested as an integrated circuit, a discrete component such as a power transistor, a passive component such as a transformer or a filter, a micro electromechanical system (MEMS) component, a sensor, an actuator, a microfluidic component, or an electro-optical component such as a micro-mirror array component, by way of example. The microelectronic component 108 may be attached to the die pad 106 by a die attach material 110, such as solder, an electrically conductive adhesive, an electrically insulating adhesive, or a eutectic metal alloy. Additional microelectronic components, not specifically shown, are attached to the additional die pads of the additional semiconductor packages 100a.

Electrical connections 112 are formed between the microelectronic component 108 and the leads 104. The electrical connections 112 may be implemented as wire bonds 112, as depicted in FIG. 1A and FIG. 1B. Alternatively, the electrical connections 112 may be implemented as ribbon bonds, clips, leads on resin coated copper, or solder bumps, by way of example.

Mold compound 114 is formed on the lead frame 102 including on the leads 104 and the additional leads 104a, the microelectronic component 108, and the electrical connections 112. The mold compound 114 in this example is formed between a bottom mold plate 116a and a top mold plate 116b. The bottom mold plate 116a contacts bottom surfaces of the leads 104. The mold compound 114 is electrically insulating. The mold compound 114 may include epoxy, by way of example. The mold compound 114 may include filler particles, such as silicon dioxide particles or aluminum oxide particles, to reduce a thermal expansion coefficient of the mold compound 114.

FIG. 1C is a top view of the semiconductor package 100 and FIG. 1D is a cross section of the semiconductor package 100 of FIG. 1C at a subsequent stage of formation. Referring to FIG. 1C and FIG. 1D, the mold compound 114 is laterally recessed to provide a relief recess 118 in the mold compound 114 over the leads 104, and to provide additional relief recesses 118a in the mold compound 114 over the additional leads 104a. In this example, the relief recess 118 and the additional relief recesses 118a are formed by a relief sawing operation using a relief saw blade 120. The relief recess 118 has a relief width 122, in a direction perpendicular to a perimeter 124 of the semiconductor package 100, greater than a lead thickness 126 of the leads 104 under the relief recess 118. The relief saw blade 120 may form the relief recess 118 and the additional relief recesses 118a in a single pass, as indicated in FIG. 1D. Alternatively, the relief recess 118 and the additional relief recesses 118a may be formed by two or more passes of the relief saw blade 120. Forming the relief recess 118 by the relief sawing operation may advantageously provide flexibility for accommodating a variety of package dimensions and may advantageously provide low fabrication cost compared to forming the relief recess 118 using package-specific molds. In this example, top surfaces of the leads 104 are not exposed by formation of the relief recess 118, that is, a portion of the mold compound 114 is left over the leads 104 under the relief recess 118, which may advantageously protect the leads 104 from contamination or chemical degradation.

FIG. 1E is a top view of the semiconductor package 100 and FIG. 1F is a cross section of the semiconductor package 100 of FIG. 1E at a subsequent stage of formation. Referring to FIG. 1E and FIG. 1F, the semiconductor package 100 and the additional semiconductor packages 100a are mounted onto a saw tape 128, also referred to as a saw film 128. The semiconductor package 100 is singulated from the additional semiconductor packages 100a by a singulation sawing process using a singulation saw blade 130. The singulation sawing process cuts through, and separates, the leads 104 of the semiconductor package 100 and the additional leads 104a of the additional semiconductor packages 100a, as well as the mold compound 114 between the semiconductor package 100 and the additional semiconductor packages 100a. The semiconductor package 100 and the additional semiconductor packages 100a are subsequently removed from the saw tape 128. The singulation sawing process produces exposed side faces 132 of the leads 104. A majority of exposed side faces 132 are characteristic of sawn surfaces. Details of the exposed side faces 132 being characteristic of sawn surfaces are disclosed in reference to FIG. 8.

FIG. 1G is a perspective of the semiconductor package 100 after singulation, and FIG. 1H is a cross section of the semiconductor package 100 of FIG. 1G. Referring to FIG. 1G and FIG. 1H, a height difference 134 between the mold compound 114 under the relief recess 118 and the leads 104 under the relief recess 118 is less than the lead thickness 126 of the leads 104 under the relief recess 118, which may advantageously reduce stress in the mold compound 114 and the leads 104 compared to a similar semiconductor package having thicker mold compound over leads. A top half 138 of a side face 136 of the relief recess 118 along the mold compound 114 may be vertical with respect to a top surface 140 of the mold compound 114, providing a larger area for the top surface 140, which may advantageously facilitate a subsequent vacuum pick and place operation when soldering the semiconductor package 100 to a circuit board. An internal corner 142 of the relief recess 118 may have a rounded profile, as depicted in FIG. 1H, which may advantageously reduce stress concentration in the mold compound 114 and the leads 104.

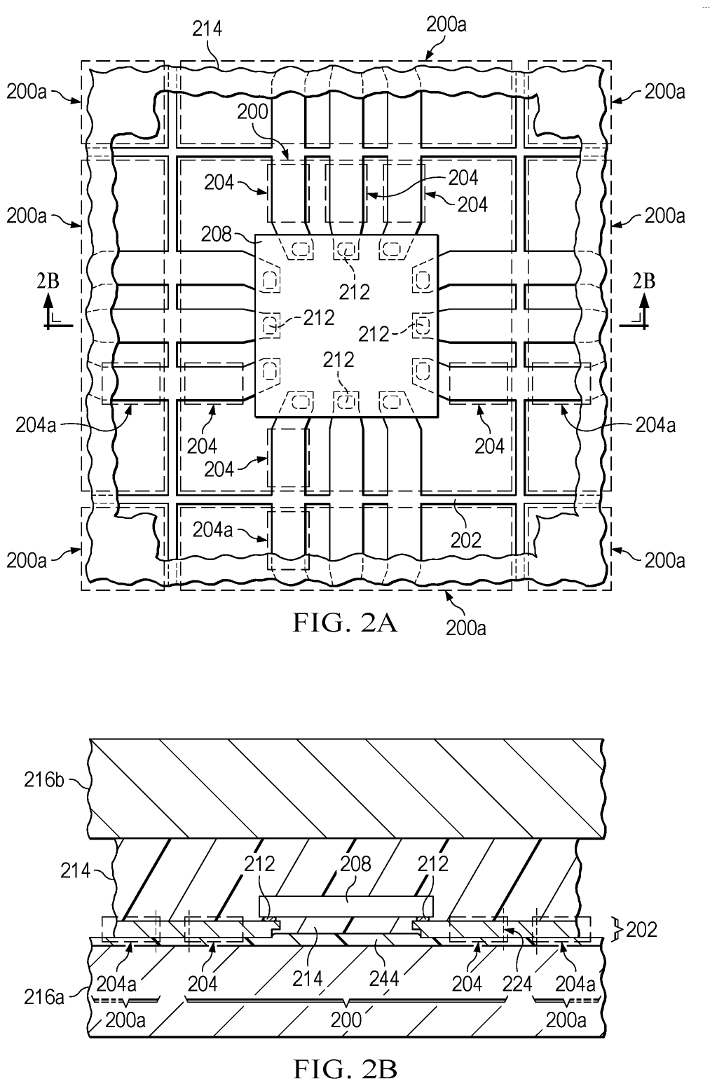

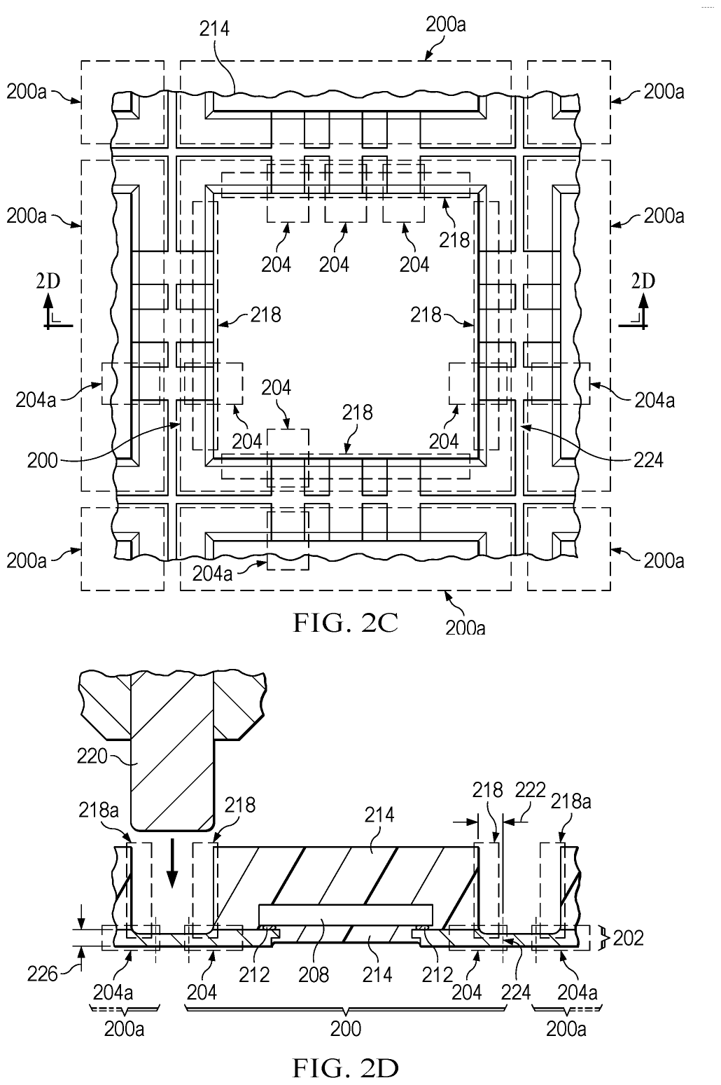

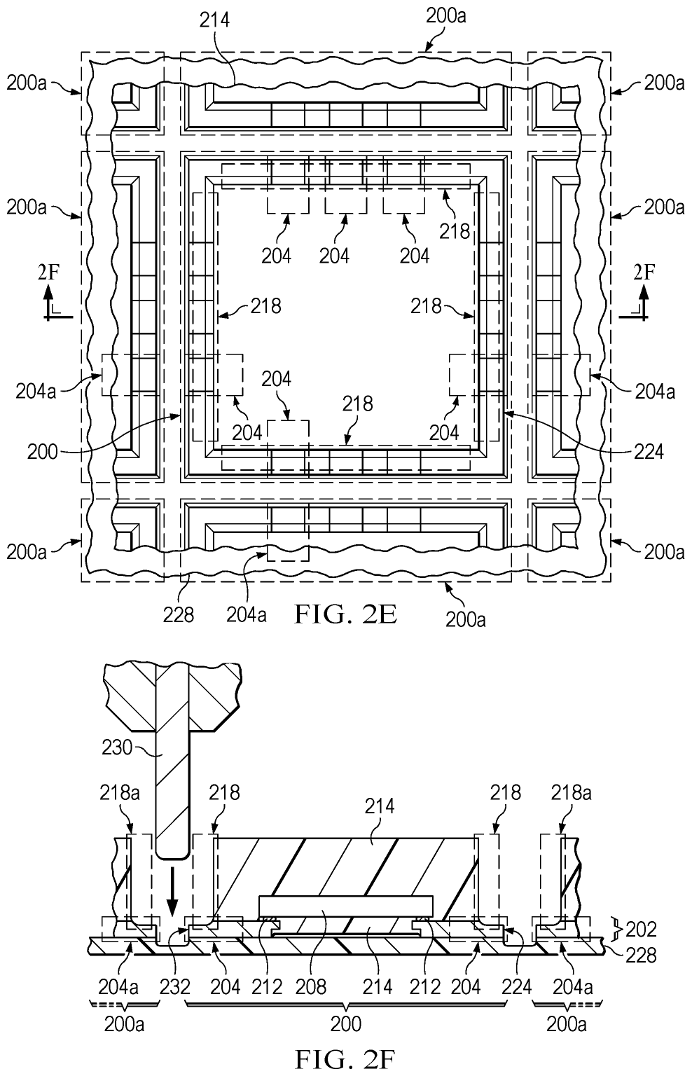

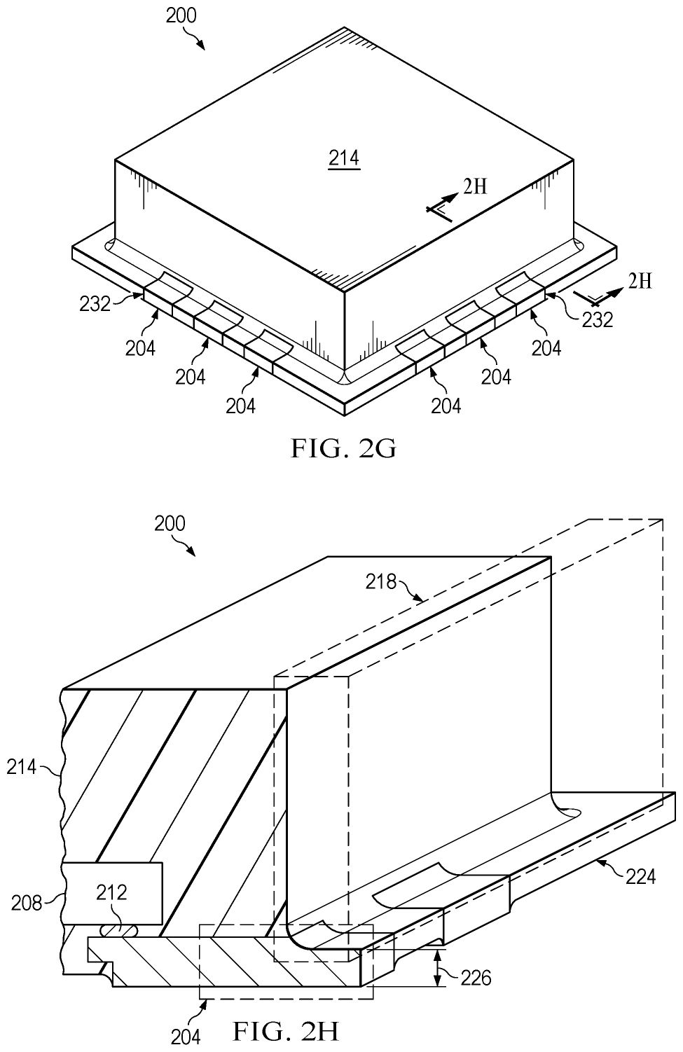

FIG. 2A through FIG. 2H are top views, cross sections, and perspectives of another semiconductor package having a relief recess, depicted in successive stages of an example method of formation. FIG. 2A is a top view of the semiconductor package and FIG. 2B is a cross section of the semiconductor package of FIG. 2A at a first stage of formation. Referring to FIG. 2A and FIG. 2B, the semiconductor package 200 is formed using a lead frame 202. The lead frame 202 of this example accommodates additional semiconductor packages 200a adjacent to the semiconductor package 200. The semiconductor package 200 includes a plurality of leads 204 of the lead frame 202. Similarly, the additional semiconductor packages 200a also include pluralities of additional leads 204a of the lead frame 202.

A microelectronic component 208 is attached to the leads 204 through electrical connections 212. In this example, the electrical connections 212 may be implemented as solder bumps, as depicted in FIG. 2A and FIG. 2B. Additional microelectronic components, not specifically shown, are attached to the additional leads 204a of the additional semiconductor packages 200a.

Mold compound 214 is formed on the lead frame 202 including on the leads 204 and the additional leads 204a, the microelectronic component 208, and the electrical connections 212. The mold compound 214 in this example is formed between a bottom mold plate 216a and a top mold plate 216b. In this example, a compressible mold release film 244 is located between the bottom mold plate 216a and bottom surfaces of the leads 204. The mold compound 214 is electrically insulating. The compressible mold release film 244 compresses between the bottom mold plate 216a and the leads 204, recessing the mold compound 214 from the bottom surfaces of the leads 204, so that leads 204 extend below a bottom surface of the mold compound 214.

FIG. 2C is a top view of the semiconductor package 200 and FIG. 2D is a cross section of the semiconductor package 200 of FIG. 2C at a subsequent stage of formation. Referring to FIG. 2C and FIG. 2D, a relief recess 218 is formed in the mold compound 214 over the leads 204, and additional relief recesses 218a are formed in the mold compound 214 over the additional leads 204a. In this example, the relief recess 218 and the additional relief recesses 218a are formed by a relief sawing operation using a relief saw blade 220, similar to the process disclosed in reference to FIG. 1C and FIG. 1D. In this example, the relief saw blade 220 cuts down to the leads 204, exposing top surfaces of the leads 204 under the relief recess 218, which may advantageously provide further stress relief compared to a similar semiconductor package with mold compound covering the leads. In this example, the relief saw blade 220 may optionally remove a portion of the leads 204. The relief recess 218 has a relief width 222, in a direction perpendicular to a perimeter 224 of the semiconductor package 200, greater than a lead thickness 226 of the leads 204 under the relief recess 218.

FIG. 2E is a top view of the semiconductor package 200 and FIG. 2F is a cross section of the semiconductor package 200 of FIG. 2E at a subsequent stage of formation. Referring to FIG. 2E and FIG. 2F, the semiconductor package 200 and the additional semiconductor packages 200a are mounted onto a saw tape 228. The semiconductor package 200 is singulated from the additional semiconductor packages 200a by a singulation sawing process using a singulation saw blade 230. The singulation sawing process cuts through, and separates, the leads 204 of the semiconductor package 200 from the lead frame 202, and similarly for the additional leads 204a of the additional semiconductor packages 200a. The sawing process cuts through, and separates, the mold compound 214 between the semiconductor package 200 and the additional semiconductor packages 200a as well. The semiconductor package 200 and the additional semiconductor packages 200a are subsequently removed from the saw tape 228. The singulation sawing process produces exposed side faces 232 of the leads 204. A majority of exposed side faces 232 are characteristic of sawn surfaces.

FIG. 2G is a perspective of the semiconductor package 200 after singulation, and FIG. 2H is a cross section of the semiconductor package 200 of FIG. 2G. Referring to FIG. 2G and FIG. 2H, the mold compound 214 under the relief recess 218 and the leads 204 under the relief recess 218 are substantially coplanar, as a result of the relief sawing operation cutting down to the leads 204, exposing the top surfaces of the leads 204. Thus, a height difference between the mold compound 214 under the relief recess 218 and the leads 204 under the relief recess 218 is approximately zero, and, in any case, is much less than the lead thickness 226 of the leads 204 under the relief recess 218, which may advantageously reduce stress in the mold compound 214 and the leads 204.

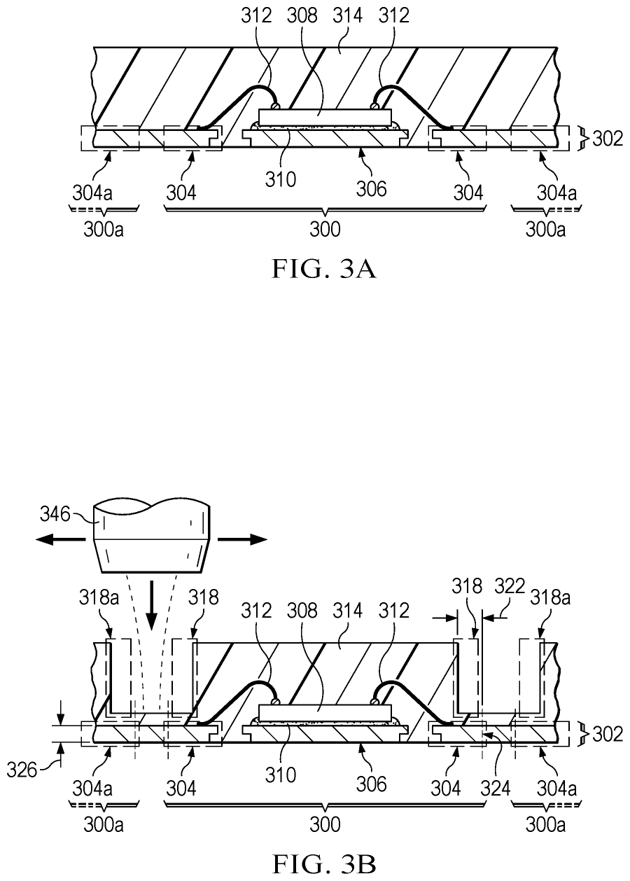

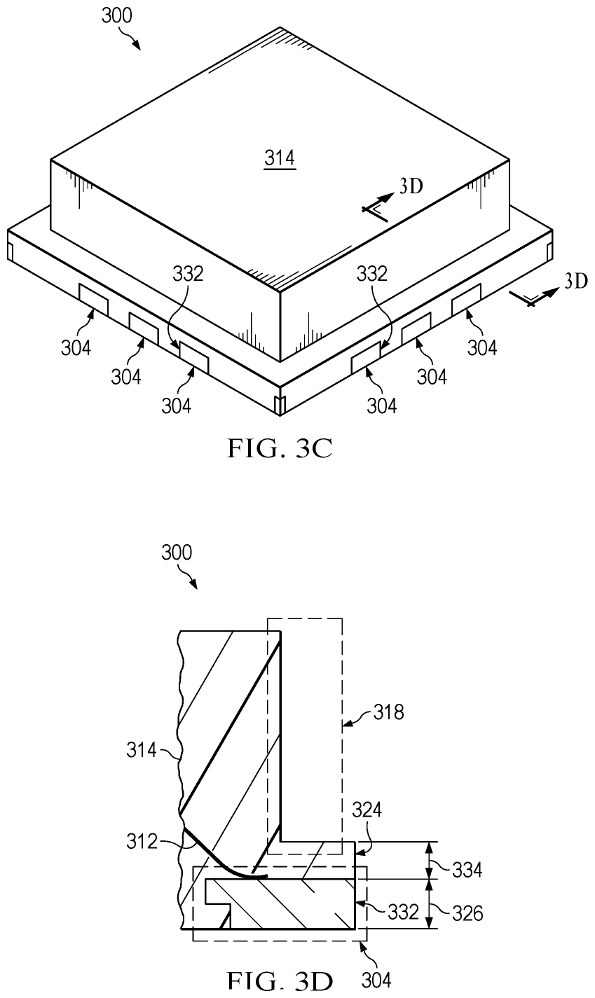

FIG. 3A through FIG. 3D are cross sections and perspectives of a further semiconductor package having a relief recess, depicted in successive stages of an example method of formation. FIG. 3A is a cross section of the semiconductor package at a first stage of formation. Referring to FIG. 3A, the semiconductor package 300 is formed using a lead frame 302. The lead frame 302 of this example may accommodate additional semiconductor packages 300a adjacent to the semiconductor package 300. The semiconductor package 300 includes a plurality of leads 304 and a die pad 306, of the lead frame 302. Similarly, the additional semiconductor packages 300a each include pluralities of additional leads 304a and additional die pads, not shown, of the lead frame 302.

A microelectronic component 308 is attached to the die pad 306 by a die attach material 310. Additional microelectronic components, not specifically shown, are attached to the additional die pads of the additional semiconductor packages 300a. Electrical connections 312, implemented as wire bonds 312 in this example, are formed between the microelectronic component 308 and the leads 304. Additional electrical connections are formed between the additional microelectronic components and the additional leads 304a.

Mold compound 314 is formed on the lead frame 302 including on the leads 304 and the additional leads 304a, the microelectronic component 308 and the additional microelectronic components, and the electrical connections 312 and the additional electrical connections. The mold compound 314 may be formed using mold plates, as disclosed in reference to FIG. 1B. The mold compound 314 is electrically insulating.

FIG. 3B is a cross section of the semiconductor package 300 at a subsequent stage of formation. The mold compound 314 is laterally recessed to provide a relief recess 318 over the leads 304, and to provide additional relief recesses 318a over the additional leads 304a. In this example, the relief recess 318 and the additional relief recesses 318a may be formed by an ablation process operation using a laser ablation tool 346 to remove material from the mold compound 314. The relief recess 318 has a relief width 322, in a direction perpendicular to a perimeter 324 of the semiconductor package 300, greater than a lead thickness 326 of the leads 304 under the relief recess 318. In one version of this example, the laser ablation tool 346 may be moved in two orthogonal directions over the semiconductor package 300 while the semiconductor package 300 is held stationary, to form the relief recess 318. In another version, the laser ablation tool 346 may be held stationary while the semiconductor package 300 is moved in two orthogonal directions under the laser ablation tool 346. In a further version, the laser ablation tool 346 may be moved in a first direction while the semiconductor package 300 is moved in a second, orthogonal, direction. In this example, top surfaces of the leads 304 are not exposed by formation of the relief recess 318, that is, a portion of the mold compound 314 is left over the leads 304 under the relief recess 318, which may advantageously protect the leads 304 from contamination or chemical degradation. Forming the relief recess 318 by the ablation process operation using the laser ablation tool 346 may advantageously improve throughput and reduce breakage compared to sawing.

Subsequently, the semiconductor package 300 is singulated from the additional semiconductor packages 300a by a singulation sawing process using a saw blade, not specifically shown. The singulation sawing process cuts through, and separates, the leads 304 of the semiconductor package 300 from the lead frame 302, and similarly for the additional leads 304a of the additional semiconductor packages 300a. The sawing process cuts through, and separates, the mold compound 314 between the semiconductor package 300 and the additional semiconductor packages 300a as well. The singulation sawing process produces exposed side faces 332, shown in FIG. 3C, of the leads 304, a majority of the exposed side faces 332 are characteristic of sawn surfaces.

FIG. 3C is a perspective of the semiconductor package 300 after singulation, and FIG. 3D is a cross section of the semiconductor package 300 of FIG. 3C. Referring to FIG. 3C and FIG. 3D, a height difference 334 between the mold compound 314 under the relief recess 318 and the leads 304 under the relief recess 318 is less than the lead thickness 326 of the leads 304 under the relief recess 318, which may accrue the advantage of reduced stress in the mold compound 314 and the leads 304.

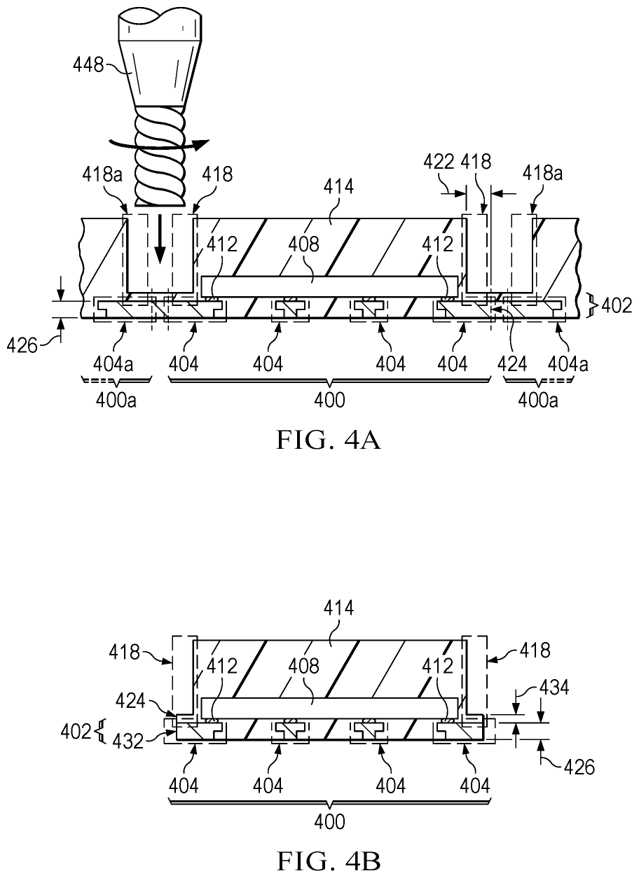

FIG. 4A and FIG. 4B are cross sections of another semiconductor package having a relief recess, depicted in successive stages of an example method of formation. Referring to FIG. 4A, the semiconductor package 400 is formed using a lead frame 402. The lead frame 402 of this example accommodates additional semiconductor packages 400a adjacent to the semiconductor package 400. The semiconductor package 400 includes a plurality of leads 404 of the lead frame 402. Similarly, the additional semiconductor packages 400a also include pluralities of additional leads 404a of the lead frame 402.

A microelectronic component 408 is attached to the leads 404 through electrical connections 412. In this example, the electrical connections 412 may be implemented as solder bumps. Additional microelectronic components, not specifically shown, are attached to the additional leads 404a of the additional semiconductor packages 400a.

Mold compound 414 is formed on the lead frame 402 including on the leads 404 and the additional leads 404a, the microelectronic component 408 and the additional microelectronic components, and the electrical connections 412 and the additional electrical connections. The mold compound 414 is electrically insulating.

A relief recess 418 is formed in the mold compound 414 over the leads 404, and additional relief recesses 418a are formed in the mold compound 414 over the additional leads 404a. In this example, the relief recess 418 and the additional relief recesses 418a are formed by a machining operation using a cutting tool 448 which removes the mold compound 414. Forming the relief recess 418 by the machining operation may advantageously provide lower equipment costs and higher throughput compared to other methods. The machining operation may leave top surfaces of the leads 404 covered by a portion of the mold compound 414, under the relief recess 418. Alternatively, the top surfaces of the leads 404 may be exposed by formation of the relief recess 418. The relief recess 418 has a relief width 422, in a direction perpendicular to a perimeter 424 of the semiconductor package 400, greater than a lead thickness 426 of the leads 404 under the relief recess 418.

Referring to FIG. 4B, the semiconductor package 400 is singulated by a sawing operation, which produces exposed side faces 432 of the leads 404. At least a majority of the exposed side faces 432 are characteristic of sawn surfaces. A height difference 434 between the mold compound 414 under the relief recess 418 and the leads 404 under the relief recess 418 is less than the lead thickness 426 of the leads 404 under the relief recess 418, which may accrue the advantage of reduced stress in the mold compound 414 and the leads 404.

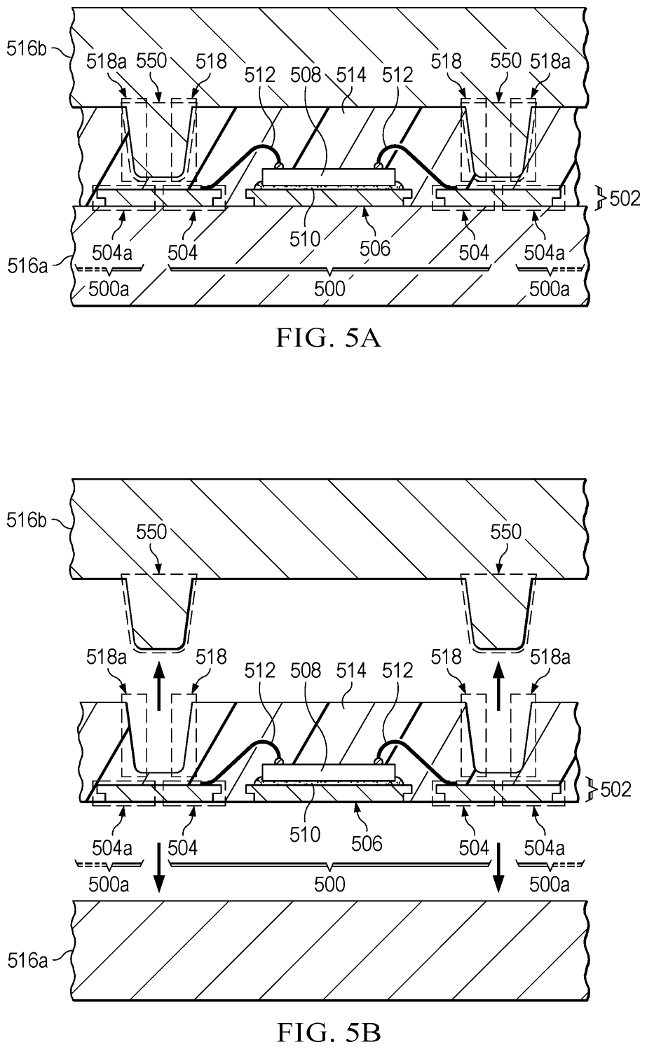

FIG. 5A through FIG. 5C are cross sections of a further semiconductor package having a relief recess, depicted in successive stages of an example method of formation. Referring to FIG. 5A, which depicts the semiconductor package 500 at a first stage of formation, the semiconductor package 500 is formed using a lead frame 502. The lead frame 502 of this example may accommodate additional semiconductor packages 500a adjacent to the semiconductor package 500. The semiconductor package 500 includes a plurality of leads 504 and a die pad 506. Similarly, the additional semiconductor packages 500a each include pluralities of additional leads 504a and additional die pads, not specifically shown.

A microelectronic component 508 is attached to the die pad 506 by a die attach material 510. Additional microelectronic components, not specifically shown, are attached to the additional die pads of the additional semiconductor packages 500a. Electrical connections 512, which may be implemented as wire bonds 512, are formed between the microelectronic component 508 and the leads 504. Additional electrical connections, not specifically shown, are formed between the additional microelectronic components and the additional leads 504a.

Mold compound 514 is formed on the lead frame 502 including on the leads 504 and the additional leads 504a, on the microelectronic component 508 and the additional microelectronic components, and on the electrical connections 512 and the additional electrical connections. The mold compound 514 is electrically insulating. The mold compound 514 is formed between a bottom mold plate 516a and a top mold plate 516b. The top mold plate 516b of this example include relief recess projections 550 extending vertically downward, proximate to the leads 504 and the additional leads 504a, in areas for a relief recess 518 over the leads 504 and additional relief recesses 518a over the additional leads 504a. The bottom mold plate 516a contacts bottom surfaces of the leads 504.

Referring to FIG. 5B, the bottom mold plate 516a and the top mold plate 516b are separated from the semiconductor package 500 and the additional semiconductor packages 500a. The relief recess 518 and the additional relief recesses 518a are formed by the relief recess projections 550. The relief recess 518 and the additional relief recesses 518a may have tapered profiles, as depicted in FIG. 5B, to facilitate separation of the top mold plate 516b from the semiconductor package 500 and the additional semiconductor packages 500a. Forming the relief recess 518 using the relief recess projections 550 of the top mold plate 516b concurrently with forming the mold compound 514 may advantageously reduce fabrication cost and improve throughput compared to forming the relief recess 518 by a separate operation.

Referring to FIG. 5C, the semiconductor package 500 is singulated by a sawing operation, which produces exposed side faces 532 of the leads 504. At least a majority of the exposed side faces 532 are characteristic of sawn surfaces. Details of characteristic of sawn surfaces are disclosed in reference to FIG. 8.

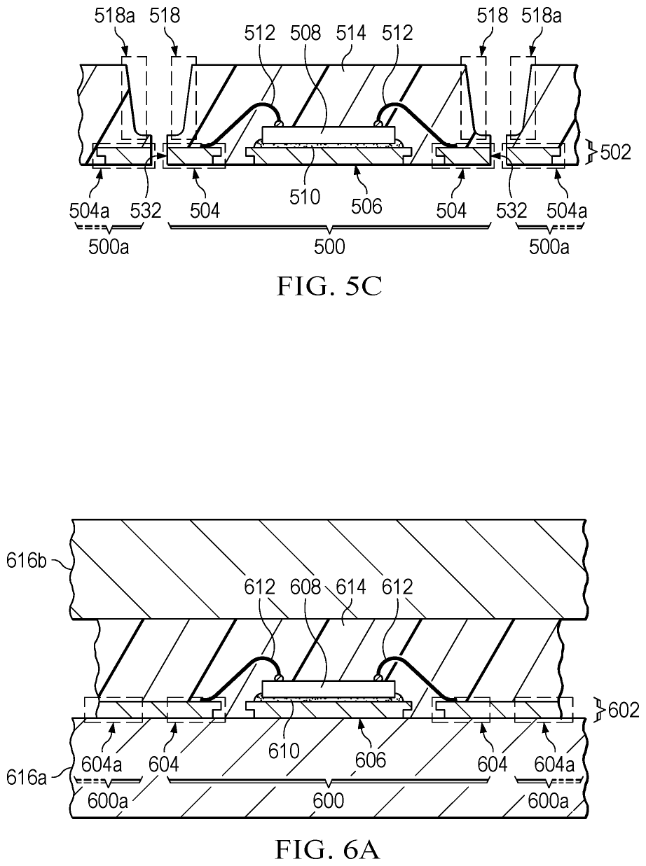

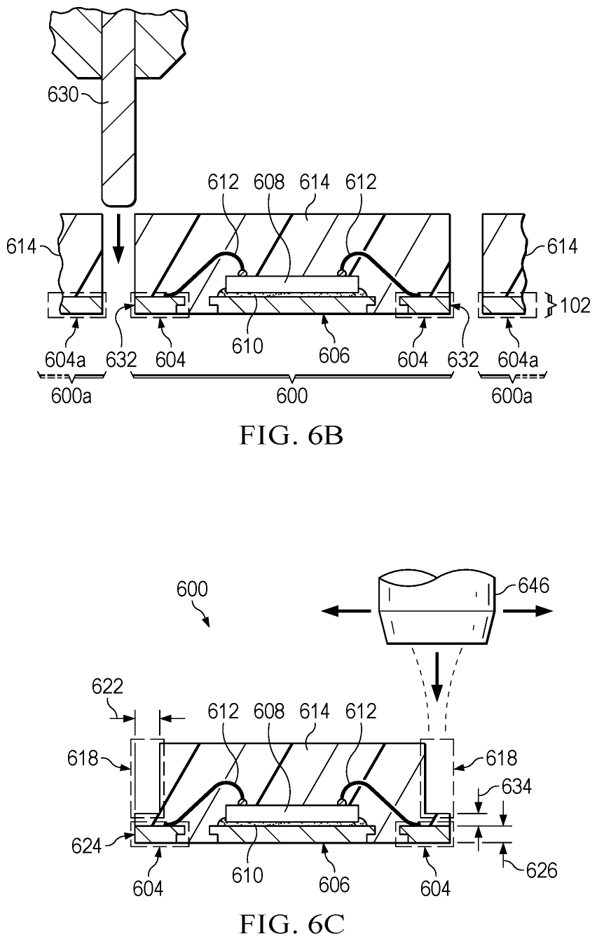

FIG. 6A through FIG. 6C are cross sections of a further semiconductor package having a relief recess, depicted in successive stages of an example method of formation. Referring to FIG. 6A, the semiconductor package 600 is depicted at a first stage of formation. The semiconductor package 600 is formed using a lead frame 602, which may accommodate additional semiconductor packages 600a adjacent to the semiconductor package 600. The semiconductor package 600 includes a plurality of leads 604 and a die pad 606, and the additional semiconductor packages 600a each include pluralities of additional leads 604a and additional die pads, not specifically shown.

A microelectronic component 608 is attached to the die pad 606 by a die attach material 610, and additional microelectronic components, not specifically shown, are attached to the additional die pads of the additional semiconductor packages 600a. Electrical connections 612 are formed between the microelectronic component 608 and the leads 604, and additional electrical connections, not specifically shown, are formed between the additional microelectronic components and the additional leads 604a.

Mold compound 614 is formed on the lead frame 602 including on the leads 604 and the additional leads 604a, on the microelectronic component 608 and the additional microelectronic components, and on the electrical connections 612 and the additional electrical connections. The mold compound 614 is electrically insulating. The mold compound 614 may be formed between a bottom mold plate 616a and a top mold plate 616b.

Referring to FIG. 6B, the semiconductor package 600 is singulated from the additional semiconductor packages 600a by a singulation sawing process using a singulation saw blade 630. The singulation sawing process cuts through, and separates, the leads 604 of the semiconductor package 600 and the additional leads 604a additional semiconductor packages 600a, as well as the mold compound 614 between the semiconductor package 600 and the additional semiconductor packages 600a. The semiconductor package 600 and the additional semiconductor packages 600a may be mounted on a sawing tape or other substrate for the singulation sawing process. The singulation sawing process produces exposed side faces 632 of the leads 604; a majority of the exposed side faces 632 are characteristic of sawn surfaces.

Referring to FIG. 6C, subsequent to singulating the semiconductor package 600, a relief recess 618 is formed in the mold compound 614 over the leads 604. The relief recess 618 may be formed by an ablation operation using a laser ablation tool 646, as depicted in FIG. 6C, or may be formed by another process, such as a machining operation or a relief sawing operation. The relief recess 618 has a relief width 622, in a direction perpendicular to a perimeter 624 of the semiconductor package 600, greater than a lead thickness 626 of the leads 604 under the relief recess 618.

In a version of this example depicted in FIG. 6C, top surfaces of the leads 604 may be left covered by a portion of the mold compound 614, under the relief recess 618. So that a height difference 634 between the mold compound 614 under the relief recess 618 and the leads 604 under the relief recess 618 is less than a lead thickness 626 of the leads 604 under the relief recess 618. In another version, the top surfaces of the leads 604 may be exposed by formation of the relief recess 618, in which case the height difference 634 between the mold compound 614 and the leads 604 is still less than the lead thickness 626 of the leads 604.

Forming the relief recess 618 subsequent to singulating the semiconductor package 600 may advantageously enable forming relief recesses in semiconductor packages held in inventory which have already been singulated, for example, as needed on a product basis.

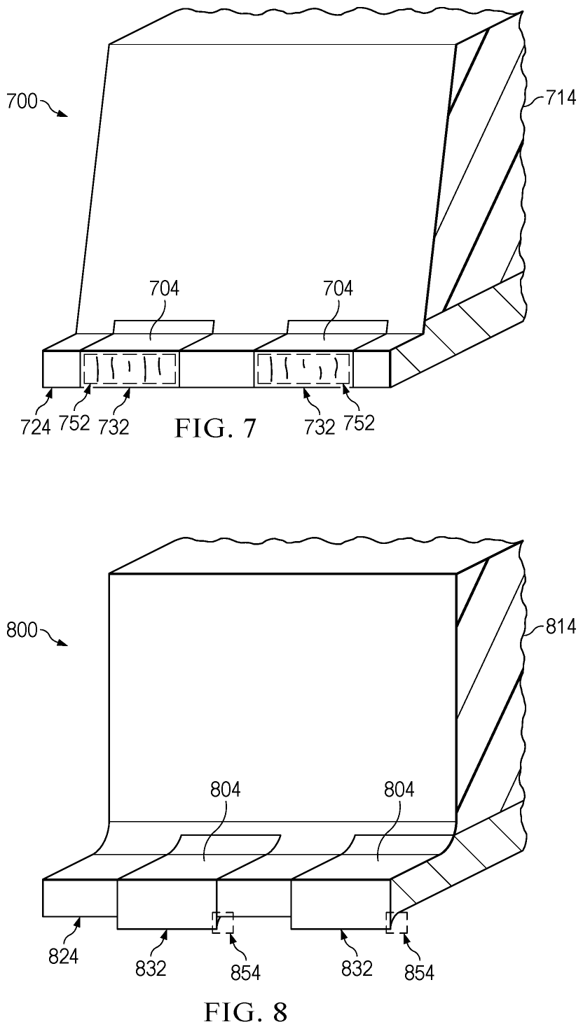

FIG. 7 is a cross section of a semiconductor package singulated by a punched process. The semiconductor package 700 includes mold compound 714 and leads 704 extending to a perimeter 724 of the semiconductor package 700. The leads 704 have exposed side faces 732 with vertical striations 752 resulting from the punched singulation process.

FIG. 8 is a cross section of a semiconductor package having exposed side faces of leads that are characteristic of sawn surfaces. The semiconductor package 800 includes mold compound 814 and leads 804 extending to a perimeter 824 of the semiconductor package 800. The leads 804 have exposed side faces 832 that are free of vertical striations, as a result of being singulated by a singulation sawing process. Having the exposed side faces 832 free of vertical striations may provide more uniform distribution of solder on the exposed side faces 832 during subsequent assembly of the semiconductor package 800 onto a substrate, such as a printed circuit board, which may advantageously provide more uniform solder joints between the leads 804 and the substrate, improving board level reliability, compared to leads having vertical striations. The leads 804 have burrs 854 along bottom edges. The burrs 854 are formed by the singulation sawing process. The burrs 854 may advantageously reduce lateral movement of the semiconductor package 800 during subsequent assembly of the semiconductor package 800 onto the substrate by adhering to solder paste on the substrate more firmly than leads lacking burrs.

Various features of the examples disclosed herein may be combined in other manifestations of example semiconductor packages. For example, any of the relief recesses 118 through 618 may be formed by a relief sawing process, an ablation process, or a machining process. Any of the relief recesses 118 through 618 may be formed to leave the leads 104 through 604, respectively, covered with the mold compound 114 through (614, respectively. Any of the relief recesses 118 through 618 may be formed to leave top surfaces of the leads 104 through 604, respectively, exposed. Any of the relief recesses 118 through 618 may be formed to have internal corner with rounded profiles.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A semiconductor package, comprising:
leads around a perimeter of the semiconductor package;
a microelectronic component electrically coupled to a plurality of the leads;
a mold compound contacting the leads and the microelectronic component, wherein:
the mold compound is electrically insulating;
the mold compound is recessed around the perimeter to provide a relief recess having a relief width greater than a thickness of the leads under the relief recess;
a height difference between the mold compound under the relief recess and the leads under the relief recess is less than the thickness of the leads under the relief recess; and
exposed side faces of a majority of the leads are characteristic of sawn surfaces.

2. The semiconductor package of claim 1, wherein a top half of a side face of the relief recess along the mold compound is vertical with respect to a top surface of the mold compound.

3. The semiconductor package of claim 1, wherein the leads are exposed at the relief recess.

4. The semiconductor package of claim 1, wherein top surfaces of the leads are exposed under the relief recess.

5. The semiconductor package of claim 1, wherein top surfaces of the leads are covered by the mold compound under the relief recess.

6. The semiconductor package of claim 1, wherein the exposed side faces of the majority of the leads being characteristic of sawn surfaces includes the exposed side faces of the majority of the leads being free of vertical striations.

7. The semiconductor package of claim 1, wherein the exposed side faces of the majority of the leads being characteristic of sawn surfaces includes the exposed side faces of the majority of the leads having burrs along bottom edges.

8. The semiconductor package of claim 1, wherein the leads extend below a bottom surface of the mold compound.

9. A method of forming a semiconductor package, comprising:
electrically coupling a microelectronic component to leads extending to a perimeter of the semiconductor package;
forming a mold compound on the leads and on the microelectronic component, the mold compound being electrically insulating;
laterally recessing the mold compound around the perimeter to provide a relief recess having a relief width greater than a thickness of the leads under the relief recess; and
singulating the semiconductor package by sawing through the leads.

10. The method of claim 9, wherein laterally recessing the mold compound produces a height difference between the mold compound under the relief recess and the leads under the relief recess that is less than the thickness of the leads under the relief recess.

11. The method of claim 9, wherein laterally recessing the mold compound is performed before singulating the semiconductor package.

12. The method of claim 9, wherein laterally recessing the mold compound is performed by removing a portion of the mold compound by a saw process.

13. The method of claim 9, wherein laterally recessing the mold compound is performed by removing a portion of the mold compound by an ablation process.

14. The method of claim 9, wherein laterally recessing the mold compound is performed by removing a portion of the mold compound by a machining process.

15. The method of claim 9, wherein laterally recessing the mold compound is performed by molding the mold compound using a mold plate with ridges corresponding to the relief recess.

16. The method of claim 9, wherein laterally recessing the mold compound exposes the leads.

17. The method of claim 9, wherein laterally recessing the mold compound removes top portions of the leads.

18. The method of claim 9, wherein the mold compound is formed so that the leads extend below a bottom surface of the mold compound.

19. The method of claim 9, wherein laterally recessing the mold compound is performed after singulating the semiconductor package.

20. A semiconductor package, comprising:
leads around a perimeter of the semiconductor package;
a microelectronic component electrically coupled to a plurality of the leads; and
a mold compound contacting the leads and the microelectronic component, wherein:
the mold compound is electrically insulating;
the mold compound is recessed around the perimeter to provide a relief recess;
the relief recess has a relief width greater than a thickness of the leads under the relief recess;
a top half of a side face of the relief recess along the mold compound is vertical with respect to a top surface of the mold compound;
an internal corner of the relief recess has a rounded profile;
a height difference between the mold compound under the relief recess and the leads under the relief recess is less than the thickness of the leads under the relief recess; and
exposed side faces of a majority of the leads are characteristic of sawn surfaces.

21. A method of forming a plurality of semiconductor packages, comprising:
electrically coupling a plurality of microelectronic components to leads of a lead frame, the leads extending to perimeters of the plurality of semiconductor packages;
forming a mold compound concurrently on the leads and on the plurality of microelectronic components, the mold compound being electrically insulating;
laterally recessing the mold compound around the perimeters to provide relief recesses having a relief width greater than a thickness of the leads under the relief recesses; and
singulating the semiconductor packages by sawing through the leads.
